(19) United States
(12) Patent Application Publication
(10) Pub. No.: US 2007/0259523 A1
(43) Pub. Date: Nov. 8, 2007

(54) Method of fabricating high speed integrated circuits

(76) Inventor: Sitaramarao Srinivas Yechuri, Las Vegas, NV (US)

Correspondence Address: Sitaramarao Srinivas Yechuri, P.O.Box 193, Lake Forest, CA, 92609, US

(21) Appl. No.: 11/418,320

(22) Filed: May 4, 2006

(51) Int. Cl. H01L 21/44

(52) U.S. Cl. 438/687

(57) ABSTRACT

This invention describes a new method of fabricating high speed chips such as microprocessors used in servers. The biggest problem limiting the speed of these chips is the heat generated by such a large number of transistors in such a small area operating at such a high frequency. This invention is a method of removing this heat in an efficient manner so that the integrated circuit can operate at a much lower temperature than is normally possible. In addition the integrated circuit area is now only limited by the size of the metal bar. The metal bar also provides new opportunities for automation of the fabrication process.

### TECHNICAL FIELD OF THE INVENTION

This invention relates generally to fabrication of semiconductor integrated circuits and specifically to high speed—large area integrated circuits used in high speed computers.

### BACKGROUND ART

In U.S. Pat. No. 6,943,107 Sandhu, et al. describe a method of forming a crystalline phase material includes, a) providing a stress inducing material within or operatively adjacent a crystalline material of a first crystalline phase; and b) annealing the crystalline material of the first crystalline phase under conditions effective to transform it to a second crystalline phase. The stress inducing material preferably induces compressive stress within the first crystalline phase during the anneal to the second crystalline phase to lower the required activation energy to produce a more dense second crystalline phase. The main thing to note in this patent in that the inventor is not depositing a layer of semiconductor of an area sufficient to fabricate an integrated circuit in, on a metal bar and then fabricating an integrated circuit in that semiconductor layer.

In U.S. Pat. No. 6,946,065 Mayer, et al. describe several techniques for reducing or mitigating the formation of seams and/or voids in electroplating the interior regions of microscopic recessed features. Cathodic polarization is used to mitigate the deleterious effects of introducing a substrate plated with a seed layer into an electroplating solution. Also described are diffusion-controlled electroplating techniques to provide for bottom-up filling of trenches and vias, avoiding thereby sidewalls growing together to create seams/voids. A preliminary plating step is also described that plates a thin film of conductor on the interior surfaces of features leading to adequate electrical conductivity to the feature bottom, facilitating bottom-up filling. The main thing to note in this patent in that the inventor is not depositing a layer of semiconductor of an area sufficient to fabricate an integrated circuit in, on a metal bar and then fabricating an integrated circuit in that semiconductor layer.

In U.S. Pat. No. 6,949,781 Chang, et al. describe a metal-over-metal (MOM) device and the method for manufacturing same is provided. The device has at least one device cell on a first layer comprising a frame piece and a center piece surrounded by the frame piece. The center piece has a cross-shape center portion defining four quadrants of space between the frame and center pieces. The center piece has one or more center fingers each extending from at least one of the four ends thereof within a quadrant. The frame piece also has one or more frame fingers extending therefrom, each being in at least one quadrant and not being overlapped with the center finger in the same quadrant. The main thing to note in this patent in that the inventor is not depositing a layer of semiconductor of an area sufficient to fabricate an integrated circuit in, on a metal bar and then fabricating an integrated circuit in that semiconductor layer.

In U.S. Pat. No. 6,955,983 Yun, et al. describe the fabrication of a metal interconnection of a semiconductor device by forming a dielectric pattern including a hole therein on a substrate, and forming a barrier metal layer in the hole and on the dielectric layer pattern outside the hole. At least some of the barrier metal layer is oxidized. An anti-nucleation layer is selectively formed on the oxidized barrier metal layer outside the hole that exposes the oxidized barrier metal layer in the hole. A metal layer then is selectively formed on the exposed oxidized barrier layer in the hole. The main thing to note in this patent in that the inventor is not depositing a layer of semiconductor of an area sufficient to fabricate an integrated circuit in, on a metal bar and then fabricating an integrated circuit in that semiconductor layer.

In U.S. Pat. No. 6,962,835 Tong, et al. describe a bonded device structure including a first substrate having a first set of metallic bonding pads, preferably connected to a device or circuit, and having a first non-metallic region adjacent to the metallic bonding pads on the first substrate, a second substrate having a second set of metallic bonding pads aligned with the first set of metallic bonding pads, preferably connected to a device or circuit, and having a second non-metallic region adjacent to the metallic bonding pads on the second substrate, and a contact-bonded interface between the first and second set of metallic bonding pads formed by contact bonding of the first non-metallic region to the second non-metallic region. At least one of the first and second substrates may be elastically deformed. The main thing to note in this patent in that the inventor is not depositing a layer of semiconductor of an area sufficient to fabricate an integrated circuit in, on a metal bar and then fabricating an integrated circuit in that semiconductor layer. In U.S. Pat. No. 6,977,435 Kim, et al. describe a process flow to make an interconnect structure with one or more thick metal layers under Controlled Collapse Chip Connection (C4) bumps at a die or wafer level. The interconnect structure may be used in a backend interconnect of a microprocessor. The one or more integrated thick metal layers may improve power delivery and reduce mechanical stress to a die at a die/package interface. The main thing to note in this patent in that the inventor is not depositing a layer of semiconductor of an area sufficient to fabricate an integrated circuit in, on a metal bar and then fabricating an integrated circuit in that semiconductor layer.

In U.S. Pat. No. 6,989,897 Chan, et al. describe methods and apparatus concerning Raman spectroscopy using metal coated nanocrystalline porous silicon substrates. Porous silicon substrates may be formed by anodic etching in dilute hydrofluoric acid. A thin coating of a Raman active metal, such as gold or silver, may be coated onto the porous silicon by cathodic electromigration or any known technique. The main thing to note in this patent in that the inventor is not depositing a layer of semiconductor of an area sufficient to fabricate an integrated circuit in, on a metal bar and then fabricating an integrated circuit in that semiconductor layer.

In U.S. Pat. No. 6,992,891 Mallik, et al. describe an assembly including a heat dissipation device having an attachment surface, a substrate having an attachment surface, and a plurality of metal balls extending between the heat dissipation device attachment surface and the substrate attachment surface. The assembly may include at least one microelectronic die disposed between the heat dissipation device attachment surface and the substrate attachment surface. The main thing to note in this patent in that the inventor is not depositing a layer of semiconductor of an area sufficient to fabricate an integrated circuit in, on a metal bar and then fabricating an integrated circuit in that semiconductor layer.

In U.S. Pat. No. 6,992,919 Andrei, et al. describe a three-dimensional circuit and methods for fabricating such a circuit are described. The three-dimensional circuit includes a plurality of stacked levels on a substrate. Each level includes a plurality of all-metal circuit components exhibiting giant magnetoresistance and arranged in two dimensions, the circuit further includes an interconnect for providing interconnections between the circuit components on different ones of the plurality of levels. The main thing to note in this patent in that the inventor is not depositing a layer of semiconductor of an area sufficient to fabricate an integrated circuit in, on a metal bar and then fabricating an integrated circuit in that semiconductor layer.

### SUMMARY OF THE INVENTION

In this invention a method of fabricating high speed chips is described. The basis for the fabrication is a metal bar upon which semiconductor is deposited. Within the metal bar are features such as a channel through which cooling fluid can be passed. The surface of the metal bar is prepared with furrows and projections to improve the adhesion of semiconductor onto it. The deposited semiconductor is recrystallized prior to fabricating the integrated circuit in it.

### BRIEF DESCRIPTION OF THE SEVERAL VIEWS OF THE DRAWINGS

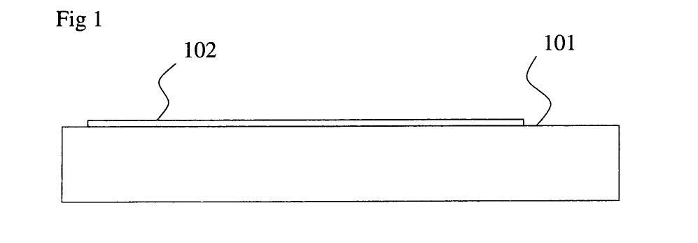

In it's simplest embodiment this invention requires a metal bar 101 as shown in the figure FIG. 1, with a layer of semiconductor 102 deposited upon the metal bar, and in this semiconductor layer 102 is fabricated an integrated circuit.

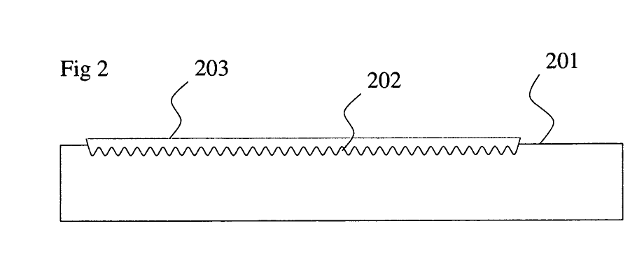

An alternate embodiment of this invention is shown in the figure FIG. 2. 201 is a metal bar with ridges and furrows marked 202. 203 is a layer of semiconductor deposited upon the metal bar, and in this semiconductor layer 203 is fabricated an integrated circuit.

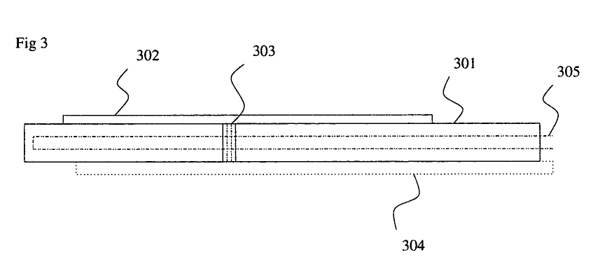

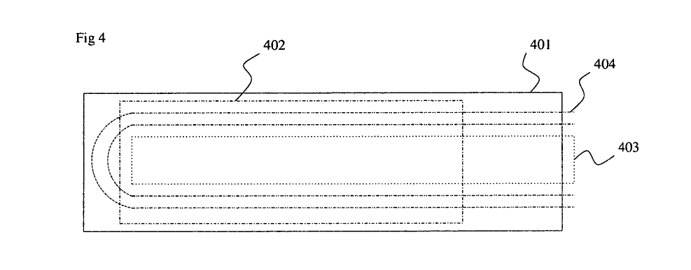

An alternate embodiment of this invention is shown in the figure FIG. 3. 301 is a metal bar upon which a layer of semiconductor 302 is deposited, and in this semiconductor layer 302 is fabricated an integrated circuit. 303 are tubes of high temperature insulator such as ceramic, enclosing a metal connector. 304 is a printed circuit board which is electrically connected to the connectors of 303. The other side of the connectors are electrically connected to the semiconductor layer which is patterned to use these connectors 303 to communicate with the printed circuit board. In addition the metal bar can have an internal channel 305 which can be used to conduct coolant fluid. The top view of this embodiment is shown in the figure FIG. 4. 401 is the metal bar marked 301 in the figure FIG. 3. 402 is the semiconductor layer marked 302 in the figure FIG. 3. 403 is the printed circuit board marked 304 in the figure FIG. 3. 404 is the internal channel marked 305 in the figure FIG. 3. The connectors marked 303 in the figure FIG. 3 are not shown in the figure FIG. 4.

What is claimed is:

1. A method of fabricating a semiconductor integrated circuit comprising the steps of:
selecting a metal bar of high thermal conductivity
depositing a layer of semiconductor on the metal bar
fabricating an intergrated circuit in the semiconductor layer

2. The method of claim 1 wherein a layer of material with intermediate physical properties between metal and semiconductor is deposited on the metal prior to depositing the semiconductor layer

3. The method of claim 1 wherein a layer of material which adheres strongly to both metal and semiconductor is deposited on the metal prior to depositing the semiconductor layer

4. The method of claim 1 wherein interconnects consisting of tubes of high temperature insulator such as ceramic enclosing a conductor such as metal are embedded in the metal bar thereby allowing electrical connections to be made to the semiconductor layer from the other side of the metal bar

5. The method of claim 1 wherein the metal bar contains grooves and ridges to allow better physical contact between the metal bar and the semiconductor layer

6. The method of claim 4 wherein a printed circuit board is electrically connected to the interconnects on the other side of the metal bar from the semiconductor layer

7. The method of claim 1 wherein the metal bar further contains an internal channel through which thermal coolant fluid may be passed

8. The method of claim 1 wherein the deposition of the semiconductor layer on the metal bar is achieved by sputtering molten semiconductor onto the metal bar

9. The method of claim 1 wherein the deposition of the semiconductor layer on the metal bar is achieved by electro-deposition i.e. by immersing the metal bar in an electrolyte bath and passing an electric current between the metal bar and the electrolyte bath

10. The method of claim 2 wherein the layer of material with intermediate physical properties between metal and semiconductor is achieved by first depositing a thin layer of semiconductor on the metal bar and then sintering i.e. localized heating perhaps through the use of a laser flash-lamp
